(19) United States
(12) Patent Application Publication
(10) Pub. No.: US 2007/0224784 A1
(43) Pub. Date: Sep. 27, 2007

(54) Semiconductor material having an epitaxial layer formed thereon and methods of making same

(76) Inventors: Stanislav Ivanovich Soloviev, Albany, NY (US); Larry Burton Rowland, Scotia, NY (US); Stephen Daley Arthur, Glenville, NY (US)

Correspondence Address: GENERAL ELECTRIC COMPANY (PCPI);C/O FLETCHER YODER, P. O. BOX 692289, HOUSTON, TX, 77269-2289, US

(21) Appl. No.: 11/386,128

(22) Filed: Mar. 22, 2006

(51) Int. Cl. H01L 21/20

(52) U.S. Cl. 438/478

(57) ABSTRACT

A semiconductor material having an epitaxial layer formed thereon and methods of forming an epitaxial layer on a semiconductor material are provided. The method includes disposing a masking layer and patterning the masking layer to form openings and growing an epitaxial layer through the openings and over the masking layer where the epitaxial layer is coalescent.

### BACKGROUND

The invention relates generally to semiconductor substrate and in particular to a silicon carbide semiconductor substrate and a method of forming an epitaxial layer thereon.

Silicon carbide (SiC) is a promising material in the semiconductor domain. SiC has a wide bandgap, a high breakdown electric field, a high thermal conductivity, and a high saturated electron drift velocity. However, the wide application of SiC is limited because of high substrate defect density resulting in poor quality of epitaxially grown films which prevents the fabrication of large area devices.

Various methods have been used previously to manufacture good quality SiC films. For example, epitaxial growth using a chemical vapor deposition (CVD) technique generally results in a high quality epitaxial layer. The structural quality of the grown epitaxial layers mainly depends upon the initial surface and substrate defects, which unavoidably propagate into the CVD grown layer. Though CVD techniques provide high quality SiC films, the growth rate of epitaxial films employing such techniques is disadvantageously low, on the order of about 2 micrometers per hour to about 6 micrometers per hour. Because high voltage power device applications generally employ epitaxial layers having significant thicknesses, using a CVD technique may be prohibitively time consuming and not economically viable. In contrast, it has been demonstrated that high growth rates are possible to achieve by employing sublimation epitaxy, rather than CVD techniques. However, sublimation epitaxy may disadvantageously result in poor quality of the crystal.

Although a number of advances have been made in the growth of silicon carbide and its use in devices, it is desirable to further minimize the defects in silicon carbide to make it a viable choice for commercial products. Accordingly, there exits a need for a silicon carbide substrate having relatively low defect density, which can be processed at low cost and employed in a semiconductor device.

### BRIEF DESCRIPTION

In accordance with an embodiment of the invention, a method of making a semiconductor substrate is provided. The method includes disposing a first masking layer on a semiconductor material. The method further includes patterning the first masking layer to form openings and hardening the first masking layer. The method further includes growing a first epitaxial layer over the first masking layer, such that the first epitaxial layer is coalescent. The method further includes planarizing the first epitaxial layer.

In accordance with another embodiment of the invention, a method of lateral growth is provided. The method includes disposing a masking layer on a silicon carbide semiconductor material. The method further includes patterning and hardening the masking layer, wherein the patterning includes forming a plurality of hexagonal shapes isolated from one another by openings therebetween. The method further includes growing an epitaxial layer through the openings and over the masking layer such that the epitaxial layer is coalescent. The method further includes planarizing the epitaxial layer.

In yet another embodiment of the invention, a structure including at least one semiconductor layer is provided. The structure further includes at least one masking layer over the at least one semiconductor layer, wherein the at least one masking layer includes a plurality of hexagonal shapes isolated from one another by openings therebetween. The structure further includes at least one epitaxial layer formed over the at least one masking layer, wherein the at least one epitaxial layer is coalescent.

In a further embodiment of the invention, a structure including at least one semiconductor layer and at least one masking layer over the at least one semiconductor layer is provided. The at least one masking layer includes a plurality of shapes, wherein each of the plurality of shapes is isolated from one another by openings therebetween. The structure further includes at least one epitaxial layer, wherein the at least one epitaxial layer is coalescent and wherein the defect density of the least one epitaxial layer is less than that of the at least one semiconductor layer.

In still another embodiment of the invention, a semiconductor device including at least one silicon carbide layer is provided. The device further includes at least one masking layer over the at least one silicon carbide layer and at least one silicon carbide epitaxial layer over the at least one silicon carbide layer, wherein the at least one silicon carbide epitaxial layer is coalescent. The at least one masking layer comprises graphite or tantalum carbide.

### DRAWINGS

These and other features, aspects, and advantages of the present invention will become better understood when the following detailed description is read with reference to the accompanying drawings in which like characters represent like parts throughout the drawings, wherein:

FIGS. 1-4 are cross-sectional views illustrating a process for forming an epitaxial layer on a semiconductor substrate, in accordance with exemplary embodiments of the present invention;

FIG. 5 is a schematic diagram of a mask of hexagonal topology, in accordance with embodiments of the present invention; and

FIG. 6 is a flow chart illustrating a method of fabricating a semiconductor substrate in accordance with embodiments of the present invention.

### DETAILED DESCRIPTION

Semiconductor materials such as silicon, silicon carbide, aluminum nitride, aluminum oxide, find applications in various electronic devices. Silicon carbide (SiC) is a wide band gap semiconductor material with immense potential. However, the usage of SiC as compared to silicon has been limited due to inherent structural defects in SiC. SiC exists in various crystal structures, also known as polytypes. As will be appreciated, there are as many as 200 polytypes of silicon carbide of which 3C, 4H and 6H SiC are the most common polytypes. These polytypes may be formed by a slight temperature variation during the manufacturing process. Hence, growing single crystal substrates and good quality epitaxial layers in silicon carbide has been a difficult task. As described further below, embodiments of the present invention provide improved methods for fabricating semiconductor substrates and devices incorporating the same.

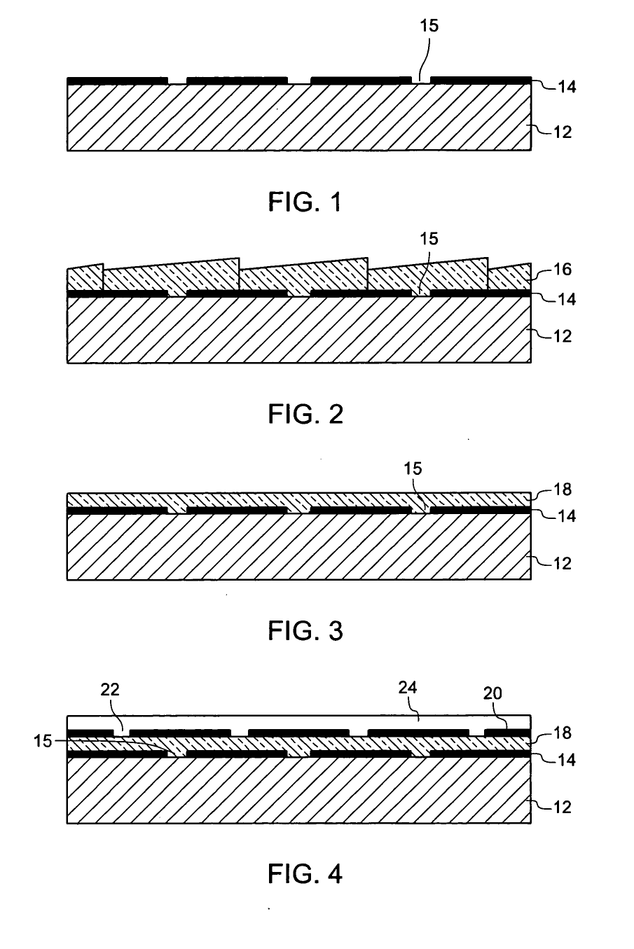

Turning now to the figures, FIGS. 1-4 illustrate an exemplary process for processing a semiconductor material to form an epitaxial layer having a reduced defect density. Specifically, FIG. 1 is a cross-sectional side view of a semiconductor material 12 having a first patterned masking layer 14 disposed thereon. The semiconductor material 12 may be a substrate on which other materials are formed, disposed and/or patterned to form one or more integrated circuit devices. Alternatively, semiconductor material 12 may be an intermediate layer of an integrated circuit device, wherein the semiconductor material 12 may be disposed on one or more underlying layers (not shown). Examples of the semiconductor material 12 include silicon carbide, aluminum nitride, or aluminum oxide. Suitable polytypes of SiC that may be used include 4H and 6H SiC polytypes. Further, the semiconductor material 12 may be p-doped, n-doped or undoped. In one embodiment, the semiconductor material 12 is single crystalline and is characterized by a low defect density which is in a range of about 10³ cm⁻² to about 10⁶ cm⁻². The semiconductor material 12 may also be a composite material including a number of semiconductor layers and these semiconductor layers may be p-doped, n-doped or undoped.

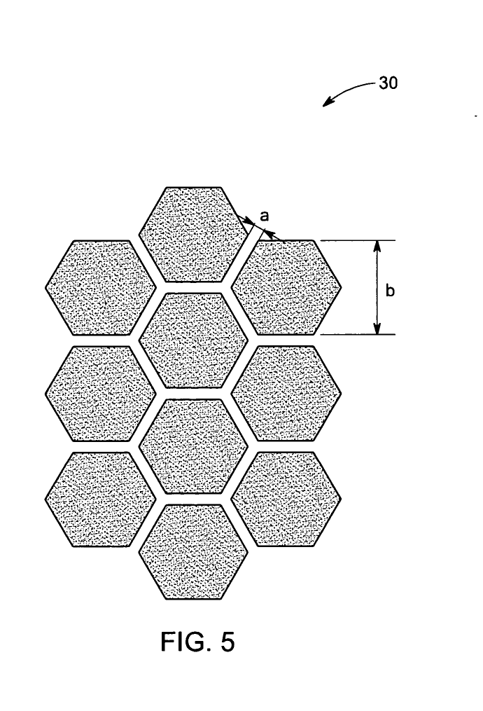

As illustrated in FIG. 1, the first patterned masking layer 14 is disposed over the semiconductor material 12. The first patterned masking layer 14 is made of a material which can withstand high temperatures, on the order of about 1800° C. to about 2200° C., for instance. Suitable masking materials may include graphite or tantalum carbide (TaC). In the illustrated example, the masking layer 14 may comprise a photoresist, although other materials may be used. As will be appreciated, exposing the photoresist to high temperatures will convert the photoresist to a hardened graphite. The pattern of the first masking layer 14 includes a plurality of shapes isolated from each other by openings 15. Example mask shapes include circles, triangles, hexagons, or rectangles. In some embodiments, the mask shapes may be irregular such as, distorted circles, distorted triangles, distorted hexagons, or distorted rectangles. The isolated features or shapes will be described and illustrated further with respect to FIG. 5 below. As used herein, the “openings” may also be referred to as “trenches”. In one embodiment, the trenches or openings 15 are about 1 micron to about 5 microns deep. The depth of the trenches 15 is directly related to the thickness of the first patterned masking layer 14. The trenches or openings 15 are in a range of about 1 micron to about 20 microns wide. According to one embodiment of the invention, the area of the plurality of shapes is greater than the area of the openings 15. In one embodiment, a ratio of the area of the openings 15 to the area of the plurality of shapes is about 1:10 to about 1:1000, as described further below with respect to FIG. 5.

Referring now to FIG. 2, a cross-sectional side view of the semiconductor material 12 after a first epitaxial growth process is illustrated. As illustrated in FIG. 2, a first epitaxial layer 16 is formed over the first patterned masking layer 14 and the semiconductor material 12, as described further below. Example materials for the first epitaxial layer 16 include silicon carbide, aluminum nitride or aluminum oxide depending on the starting semiconductor material 12. For example, a homoepitaxial growth of a semiconductor material of SiC will result in a first epitaxial layer of SiC. Further, the first epitaxial layer 16 may be p-doped, n-doped or undoped.

At the initial stages of epitaxial growth, islands of crystals of the semiconductor material 12 are formed in the trenches 15 around the plurality of shapes of the first patterned masking layer 14, and with time the growth coalesces to form the first epitaxial layer 16 spanning the first patterned masking layer 14. As used herein, the first epitaxial layer 16 is said to be “coalescent” when the material growing through the openings or trenches 15 grows together or fuses. As will be appreciated, the surface of the first epitaxial layer 16 may not be smooth since the epitaxial growth progresses from the surface of the semiconductor material 12 and through the openings in the first patterned masking layer 14 before coalescing over the surface of the masking layer 14. Moreover, the rate of lateral growth may be different from the rate of vertical growth resulting in an uneven epitaxial layer 16. In one embodiment, the rate of lateral growth is about six times greater than that of the rate of vertical growth. In other words, the ratio of the rate of vertical growth to the rate of lateral growth may be about 1:6. The first epitaxial layer 16, in one embodiment, has a thickness which is in a range of about 5 microns to about 20 microns. In one embodiment, the first epitaxial layer 16 is about 0.1 centimeters to about 3 centimeters in lateral spread, and may even have a lateral spread of up to about 10.1 centimeters in diameter.

When the area of the plurality of shapes is greater than the area of the openings 15 of a first patterned masking layer 14, lateral overgrowth is preferentially promoted. As a result, the defect density of the epitaxial layer 16 is reduced by several orders, as compared to the defect density of the semiconductor material 12. In one embodiment, the defect density of the epitaxial layer is 3 orders less than that of the semiconductor material 12. In another embodiment, the defect density of the epitaxial layer 16 is in a range of about 10¹ cm⁻² to about 10² cm⁻².

After growth of the epitaxial layer 16, the uneven surface of the first epitaxial layer 16 is planarized to form the first planarized epitaxial layer 18, as illustrated in FIG. 3. The planarizing step may be performed through methods known in the art such as mechanical, chemical or chemical-mechanical planarization. The smoothness of the surface is improved after planarizing and in some cases the smoothness may be as low as 20 Å. The thickness of the planarized epitaxial layer 18 may be in a range of about 3 microns to about 100 microns, or greater than about 100 microns.

The substrate 12 after the first epitaxial growth may be further processed. In one embodiment, the first planarized epitaxial layer 18 is sliced to form a freestanding wafer of pure semiconductor material. In another embodiment, the semiconductor material 12 with the masking layer 14 and the first planarized epitaxial layer 18 is used as a seed for crystal growth. In yet another embodiment, the semiconductor material 12, with the first patterned masking layer 14 and the first planarized epitaxial layer 18 forms a component of a device. Example devices include a diode, a MOSFET, a transistor, a field effect transistor, a light emitting diode, a power electronic device, a switching device, a Schottky diode, a photodetector or any combinations thereof.

Optionally, a second epitaxial layer may be grown to obtain a desired thickness of epitaxial layers. For instance, the desired thickness of the epitaxial layers may be greater than that of the substrate with a first planarized epitaxial layer 18. FIG. 4 illustrates an increased thickness of epitaxial material, wherein a second epitaxial growth step has been performed. Elements 20 and 24 represent a second patterned masking layer and a second planarized epitaxial layer, respectively. The second patterned masking layer 20 may have similar properties as the first patterned masking layer 14. The masking material for the masking layer 20 may be photoresist baked at high temperatures to form graphite, although other materials may be used. In the illustrated example, the pattern of the second masking layer 20 is not aligned with respect to the patterns of the first masking layer 14. That is to say that the openings or trenches 22 in the second masking layer 20 do not align with the openings or trenches 15 in the first masking layer 14. Advantageously, by misaligning the masking layers in successive masking layers, the defects from one epitaxial layer (e.g., epitaxial layer 18) may not be propagated to the next, overlying epitaxial layer (e.g., epitaxial layer 24). Alternatively, the patterns of the second masking layer 20 may be aligned with respect to the patterns of the first masking layer 14.

Example materials for the planarized second epitaxial layer 24 include silicon carbide, aluminum nitride, or aluminum oxide. Further, the second planarized epitaxial layer 24 may be p-doped, n-doped or undoped. For example, in one embodiment, the first planarized epitaxial layer 18 comprises a different doping type than the second planarized epitaxial layer 24. Alternatively, the first and second epitaxial layers 18 and 24 may be of similar doping types. Further, the doping concentration of the epitaxial layers 18 and 24 may be different.

Because the first planarized epitaxial layer 18 of this embodiment forms the seed crystal for the growth of the second epitaxial layer, a defect density of the second planarized epitaxial layer 24 is generally less than that of the first planarized epitaxial layer 18. In one embodiment, the defect density of the second planarized epitaxial layer 24 is 10 times less than that of the first planarized epitaxial layer 18. In a further embodiment, the defect density of the second planarized epitaxial layer 24 is in a range of about 10 cm⁻² to about 10 ² cm⁻². The planarized second epitaxial layer 24 is further processed and in one embodiment, is sliced to form a freestanding wafer of pure semiconductor material. In one embodiment, the semiconductor material 12 with the first and second planarized epitaxial layers 18 and 24 is used as a seed for crystal growth. In yet another embodiment, the semiconductor material 12 with the patterned masking layers 14 and 20, and the planarized epitaxial layers 18 and 24, forms a component of a device. Example devices include a diode, a MOSFET, a transistor, a field effect transistor, a light emitting diode, a power electronic device, a switching device, a Schottky diode, a photodetector or any combinations thereof Optionally, the growth of epitaxial layers may be repeated any number of times to get a substrate of desired thickness and higher purity (i.e., lower defect density).

FIG. 5 depicts a top view of the mask topology 30 in accordance to one embodiment of the invention. The mask topology 30 is one exemplary embodiment of the masking layers 14 and 20 that may be employed in accordance with embodiments of the present invention. The mask has a honey comb or hexagonal structure having a plurality of hexagons isolated from one another by openings or trenches (e.g., openings 15 or 22). The “a” shown in the FIG. 5 refers to a dimension of the openings or trenches and correlates with the width of the openings. The element “b” refers to a dimension of the patterned shapes, here a hexagon, and correlates with the lateral width of the patterned shapes. The dimensions “a” and “b”of the mask are optimized to lower the defect density. That is, the area of the patterned masking layer, wherein the patterned mask material shapes remain, is much greater than the area of the openings. In some embodiments, a ratio of the area of the openings to the area of the plurality of hexagonal shapes is in a range of about 1:10 to about 1:1000. A defect density of an epitaxial layer grown using a mask of hexagonal structure, according to embodiments of the present invention, is in a range of about 10³ cm⁻² to about 10⁷ cm⁻². The corresponding “a” values are in a range of about 1 micron to about 20 microns, and the corresponding “b” values are in a range of about 20 microns to about 150 microns, or greater than about 150 microns. The thickness of the mask is about 0.1 micron to about 10 microns and is correlative to the depth of the openings.

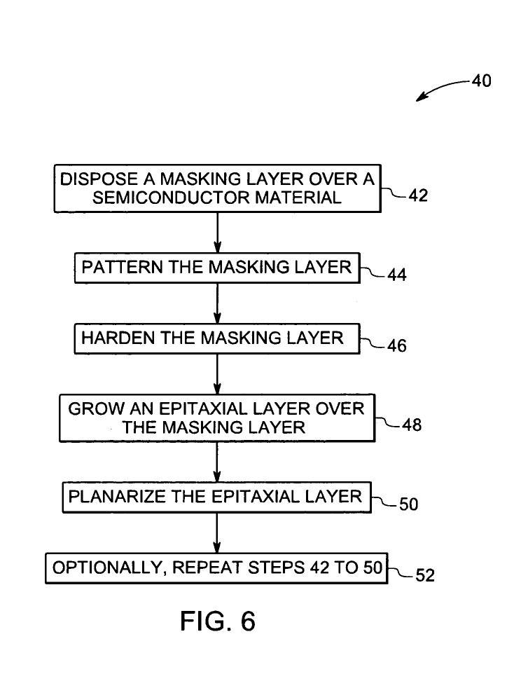

Turning now to FIG. 6, a flow chart depicting a method of growing an epitaxial film on a semiconductor material, according to one embodiment of the invention is illustrated. A starting semiconductor material layer comprising a semiconductor material is provided. The semiconductor material may comprise one of silicon carbide, aluminum nitride, or aluminum oxide and further may be p-doped, n-doped or undoped. Suitable polytypes of SiC that may be used include 4H and 6H SiC polytypes. The semiconductor material may be single crystalline with a low defect density of the order of about 10³ cm⁻² to about 10⁵ cm⁻². As previously described, the semiconductor material may comprise a substrate or wafer, or it may comprise an intermediate layer of a structure having a number of layers formed thereunder. In one example, a 6H SiC polytype layer or wafer may be used as the starting material. Initially, the SiC wafer may be cleaned using standard techniques known in the art.

At step 42, a masking layer is disposed over the 6H SiC layer. In one embodiment, the masking layer is a photoresist layer. The photoresist layer includes a thin carbon layer deposited over the 6H SiC layer. The masking layer is patterned at step 44. In one embodiment, the photoresist layer is patterned using a photomask and standard photolithographic techniques. The photomask may have patterns, which are inverse patterns of the patterns to be formed on the masking layer (i.e., the photoresist layer), as will be appreciated. For example, to form a pattern on the masking layer having a plurality of hexagonal shapes isolated from one another by openings or trenches, an inverse pattern consisting of hexagonal openings isolated from one another by photomask material may be employed. Suitable shapes of the pattern for the patterned structures include circular, triangular, hexagonal, or rectangular structures, for example. The photoresist layer is exposed to UV radiation, in one embodiment. The exposure to UV radiation results in hardening of the exposed regions of the photoresist layer if a negative tone photoresist used and in hardening of unexposed regions of the photoresist layer if a positive tone photoresist used. Subsequent to removal of the photomask, the photoresist layer is treated with a developing solution resulting in openings or trenches in the unexposed regions of the photoresist layer or the masking layer, and the underlying 6H SiC layer. The 6H SiC layer with the patterned masking layer is then transferred to a furnace. At step 46, the patterned masking layer is hardened to form graphite by subjecting the masking layer to high temperatures in oxygen-free ambient. Typical high temperatures are in a range of about 1800° C. to about 2200° C.

At step 48, a physical vapor transport or sublimation epitaxy method is employed to promote epitaxial growth. The growth is initiated from surfaces on-axis and 8° off-axis in the [1120] direction of the 6H SiC starting material. In one embodiment, source material for SiC is provided within the furnace. The source material may be single crystalline SiC, or polycrystalline SiC, or powdered SiC and further may be doped or undoped.

The pressure and temperature within the furnace is increased for an optimal growth. In one embodiment, the lateral growth rate is in a range of about 0.1 micron per minute to about 30 microns per minute. The corresponding temperature is in a range of about 1800° C. to about 2200° C. In one embodiment, the pressure is in a range of about 10⁻¹⁰ atmospheric pressure to about 2 times the atmospheric pressure. At the elevated temperature of about 1800° C. to about 2500° C., the source material sublimes and deposits on the exposed 6H SiC layer. The growth progresses through the openings in the masking layer to form islands of pure, single crystalline SiC. Since the growth is essentially from a masked starting material a lateral growth is preferentially promoted as opposed to the case where there is no masking layer.

Alternatively, precursor gases may be introduced in the furnace. Suitable precursor gases include silane. In one embodiment, dopants are introduced along with the precursor gases. In one embodiment, the flow rate of precursor gases is in a range of about 10⁻⁴ percent to about 10 percent. Suitable dopants include nitrogen and trimethyl aluminum. The precursor gases when in contact with the exposed 6H SiC layer promotes lateral overgrowth.

The epitaxial growth progresses such that islands of single crystal around the shapes of the pattern coalesce to form a fused epitaxial layer. The growth is not uniform and results in uneven surface of the epitaxial layer since substrate is axis-off oriented. As will be appreciated, the uneven surface may be undesirable in forming integrated circuit devices. Accordingly, the uneven surface may be planarized.

The epitaxial layer is planarized in step 50. Suitable methods include chemical, mechanical or chemical mechanical planarization. In one example, the SiC epitaxial layer 16 is subjected to polishing with SiC nanoparticles based slurry in a polishing system to get the roughness reduced to about 10 Åto about 20 Å, which is the typical roughness tolerable for use in devices.

Optionally at step 52, steps discussed with reference to steps 42-50 may be repeated. During a repeat of step 42, a second masking layer is disposed on the planarized epitaxial layer. The second masking layer is not aligned with respect to the first masking layer, in one embodiment. Alternatively, the second masking layer is aligned with respect to the first masking layer. Repeating the steps may increase the thickness of the structure and advantageously may further reduce the defect density of the epitaxial layer.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A method of growing an epitaxial layer on a semiconductor material comprising:
disposing a first masking layer on the semiconductor material;
patterning the first masking layer to form openings therethrough;
hardening the first masking layer;
growing a first epitaxial layer through the openings and over the first masking layer, such that the first epitaxial layer is coalescent; and
planarizing the first epitaxial layer.

2. The method of claim 1, further comprising:
disposing a second masking layer on the planarized first epitaxial layer;
patterning the second masking layer to form openings therethrough;
hardening the second masking layer;
growing a second epitaxial layer through the openings and over the second masking layer, such that the second epitaxial layer is coalescent; and
planarizing the second epitaxial layer.

3. The method of claim 2, wherein patterning the second masking layer comprises patterning the second masking layer such that patterns formed in the second masking layer are not aligned with patterns formed in the first masking layer.

4. The method of claim 1, wherein patterning the first masking layer comprises forming a plurality of shapes in the first masking layer, wherein each of the plurality of shapes is isolated from one another by the openings therebetween.

5. The method of claim 1, wherein patterning the first masking layer comprises forming a plurality of hexagonal shapes in the first masking layer, wherein each of the plurality of hexagonal shapes is isolated from one another by the openings therebetween.

6. The method of claim 5, wherein a width of the openings is in a range of about 1 micron to about 20 microns.

7. The method of claim 5, wherein a lateral width of each of the plurality of hexagonal shapes is in a range of about 20 microns to about 150 microns.

8. The method of claim 5, wherein a ratio of an area of the openings to an area of the plurality of hexagonal shapes is in a range of about 1:10 to about 1:1000.

9. The method of claim 1, wherein growing the first epitaxial layer comprises growing the first epitaxial layer at a temperature which is in a range of about 1800° C. to about 2200° C.

10. The method of claim 1, wherein growing the first epitaxial layer comprises growing the first epitaxial layer at a pressure which is in a range of about 10⁻¹⁰ atmospheric pressure to about 2 atmospheric pressure.

11. The method of claim 1, wherein growing the first epitaxial layer comprises growing the first epitaxial layer at a lateral growth rate which is in a range of about 0.1 micron per minute to about 30 microns per minute.

12. The method of claim 1, wherein growing the first epitaxial layer results in vertical growth and lateral growth, wherein a ratio of rate of vertical growth to lateral growth is about 1:6.

13. The method of claim 1, wherein growing the first epitaxial layer comprises growing by one of physical vapor transport and sublimation epitaxy.

14. The method of claim 1, wherein planarizing the first epitaxial layer comprises mechanical planarization, chemical planarization or chemical mechanical planarization.

15. The method of claim 1, wherein disposing the first masking layer comprises disposing a photoresist.

16. The method of claim 1, wherein hardening the first masking layer comprises heating the first masking layer at temperatures in a range of about 1800° C. to about 2200° C.

17. A lateral growth method comprising:
disposing a masking layer on a silicon carbide semiconductor material;
patterning the masking layer, wherein patterning the masking layer comprises forming a plurality of hexagonal shapes in the masking layer, wherein each of the plurality of hexagonal shapes is isolated from one another by openings therebetween;
hardening the masking layer;
growing an epitaxial layer through the openings and over the masking layer, such that the epitaxial layer is coalescent; and
planarizing the epitaxial layer.

18. The method of claim 17, comprising repeating each step sequentially one or more times to form a composite structure having a desired thickness or a desired defect density or both.

19. A structure comprising:
at least one semiconductor layer;
at least one masking layer over the at least one semiconductor layer, wherein the at least one masking layer comprises a plurality of hexagonal shapes, wherein each of the plurality of hexagonal shapes is isolated from one another by openings therebetween; and
at least one epitaxial layer formed over the at least one masking layer and the at least one semiconductor layer, wherein the at least one epitaxial layer is coalescent.

20. The structure of claim 19, wherein the at least one semiconductor layer comprises silicon carbide, aluminum nitride or aluminum oxide.

21. The structure of claim 19, wherein the at least one epitaxial layer comprises silicon carbide, aluminum nitride or aluminum oxide.

22. The structure of claim 19, wherein the at least one masking layer comprises graphite or tantalum carbide.

23. The structure of claim 19, wherein the structure forms a seed for crystal growth.

24. The structure of claim 19, wherein the at least one semiconductor layer comprises a substrate.

25. A structure comprising:
at least one semiconductor layer;
at least one masking layer over the at least one semiconductor layer, wherein the at least one masking layer comprises a plurality of shapes, wherein each of the plurality of shapes is isolated from one another by openings therebetween; and
at least one epitaxial layer, wherein the at least one epitaxial layer is coalescent, wherein a defect density of the at least one epitaxial layer is less than a defect density of the at least one semiconductor layer.

26. The structure of claim 25, wherein the at least one epitaxial layer has a defect density, which is in a range of about 10³ cm⁻² to about 10⁶ cm⁻².

27. The structure of claim 25, wherein the at least one semiconductor layer comprises silicon carbide, aluminum nitride or aluminum oxide.

28. The structure of claim 25, wherein the at least one epitaxial layer comprises silicon carbide, aluminum nitride or aluminum oxide.

29. The structure of claim 25, wherein the at least one masking layer comprises graphite or tantalum carbide.

30. The structure of claim 25, wherein the structure forms a seed for crystal growth.

31. The structure of claim 25, wherein a ratio of an area of the openings to an area of the plurality of shapes is about 1:10 to about 1:1000.

32. A semiconductor device comprising:
at least one silicon carbide layer;
at least one masking layer over the at least one silicon carbide layer, wherein the at least one masking layer comprises graphite or tantalum carbide; and
at least one silicon carbide epitaxial layer over the at least one masking layer and the at least one silicon carbide layer, wherein the at least one silicon carbide epitaxial layer is coalescent.

33. The semiconductor device of claim 32, wherein the at least one masking layer comprises a plurality of hexagonal shapes, wherein each of the plurality of hexagonal shapes is isolated from one another by openings therebetween.

34. The semiconductor device of claim 32, wherein the device comprises a diode, a MOSFET, a transistor, a field effect transistor, a light emitting diode, a power electronic device, a switching device, a Schottky diode, a photodetector or any combinations thereof.
